(19) United States
(12) Patent Application Publication
(10) Pub. No.: US 2022/0225510 A1
(43) Pub. Date: Jul. 14, 2022

(54) CIRCUIT BOARD AND METHOD FOR MANUFACTURING THE SAME

(71) Applicants: QING DING PRECISION ELECTRONICS (HUAIAN) CO.,LTD, Huai an (CN); Avary Holding (Shenzhen) Co., Limited., Shenzhen (CN)

(72) Inventors: HSIAO-TING HSU, New Taipei (TW); QIAN-NAN ZHOU, Shenzhen (CN); XIAN-QIN HU, Shenzhen (CN); MING-JAAN HO, New Taipei (TW); FU-YUN SHEN, Shenzhen (CN)

(21) Appl. No.: 17/709,659

(22) Filed: Mar. 31, 2022

Related U.S. Application Data
(63) Continuation-in-part of application No. PCT/CN2020/098882, filed on Jun. 29, 2020.

(51) Int. Cl. H05K 3/34; H05K 3/00; H05K 1/18

(52) U.S. Cl. CPC H05K 3/3431; H05K 3/3485; H05K 3/26; H05K 1/181; H05K 3/0035

(57) ABSTRACT

A method for manufacturing a circuit board is disclosed. An inner laminated structure with a conductive wiring layer and an outermost cover layer is provided. The conductive wiring layer includes a connection pad. A mask is disposed on a side of the cover layer away from the conductive wiring layer, and the mask defines a plurality of first openings penetrating the mask. A second opening is formed on the cover layer by laser etching through the mask to expose the connection pad. A surface treatment is applied to the connection pad and an electronic component is electrically connected with the connection pad. A circuit board is also disclosed.

### FIELD

The present disclosure relates to a circuit board and a manufacturing method thereof.

### BACKGROUND

Electronic products are widely used in daily work and life, and light, thin, and small electronic products are becoming more and more popular. As a main component of electronic products, circuit boards occupy a large amount of space in the electronic products. The size of the circuit boards greatly affects the size of the electronic products. Large-size circuit boards are difficult to be installed in thin, short, and small-size electronic products.

A solution to reduce the size of a circuit board is to improve a density of electronic components (such as resistors and capacitors) on the circuit board, and also to use smaller electronic components. To improve the density or to use smaller electronic components, pin ports with a smaller size and a higher density need to be used. The pin ports are generally formed on the circuit board by a solder mask process, but it is difficult to form pin ports with small size and high precision due to expansion and contraction of film and the influence of exposure to the environment. In addition, the pin ports formed by the solder mask process have a trapezoidal structure, which makes it difficult for gas in the pin ports to be discharged during reflow soldering with solder paste, resulting in poor soldering and reducing reliability of components.

### BRIEF DESCRIPTION OF THE DRAWINGS

The following drawn figures are to be viewed in conjunction with the embodiments described herein.

FIG. 1 is a diagrammatic view showing an inner laminated structure according to an embodiment of the present disclosure.

FIG. 2 is a schematic diagram of the inner laminated structure of FIG. 1 laser-etched through a mask.

FIG. 3 is a plan view of the inner laminated structure of FIG. 2.

FIG. 4 is a schematic diagram of a second opening with residue according to an embodiment of the present disclosure.

FIG. 5 is a schematic diagram of a surface of a connection pad exposed for a surface treatment in the second opening of FIG. 4.

FIG. 6 is a schematic diagram of a metal coating formed on the connection pad of FIG. 5.

FIG. 7 is a schematic diagram of a conductive paste formed on the metal coating of FIG. 6.

FIG. 8 is a schematic diagram of an electronic component mounted in the second opening of FIG. 7.

FIG. 9 is a schematic cross-sectional view showing a circuit board according to an embodiment of the present disclosure.

### DETAILED DESCRIPTION

The present disclosure will now be described more fully hereinafter with reference to the accompanying drawings, in which exemplary embodiments of the disclosure are shown. This disclosure may, however, be embodied in many different forms and should not be construed as limited to the exemplary embodiments set forth herein. Rather, these exemplary embodiments are provided so that this disclosure will be thorough and complete, and will fully convey the scope of the disclosure to those skilled in the art. Like reference numerals refer to like elements throughout.

The terminology used herein is for the purpose of describing particular exemplary embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

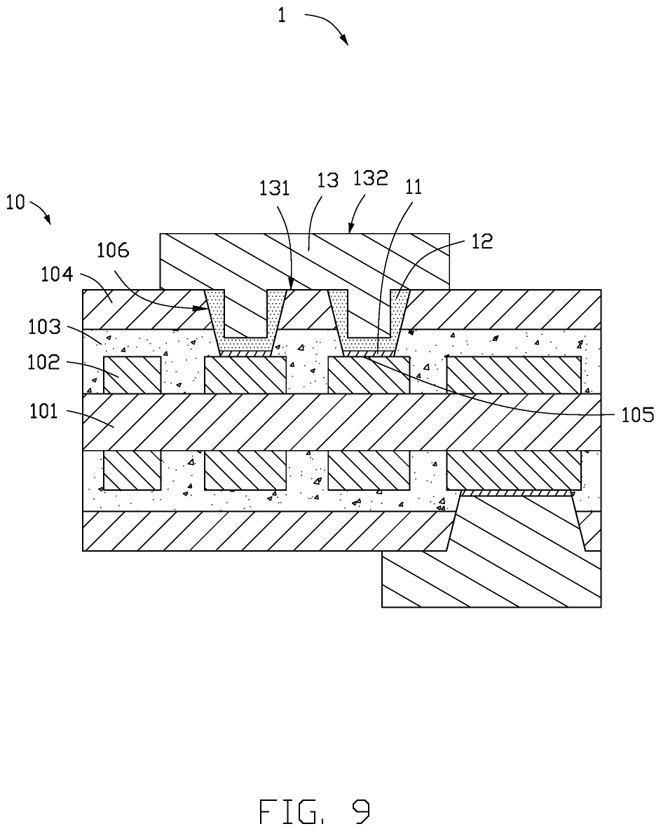

A method for manufacturing a circuit board 1 (shown in FIG. 9) according to an embodiment of the present disclosure includes the following steps:

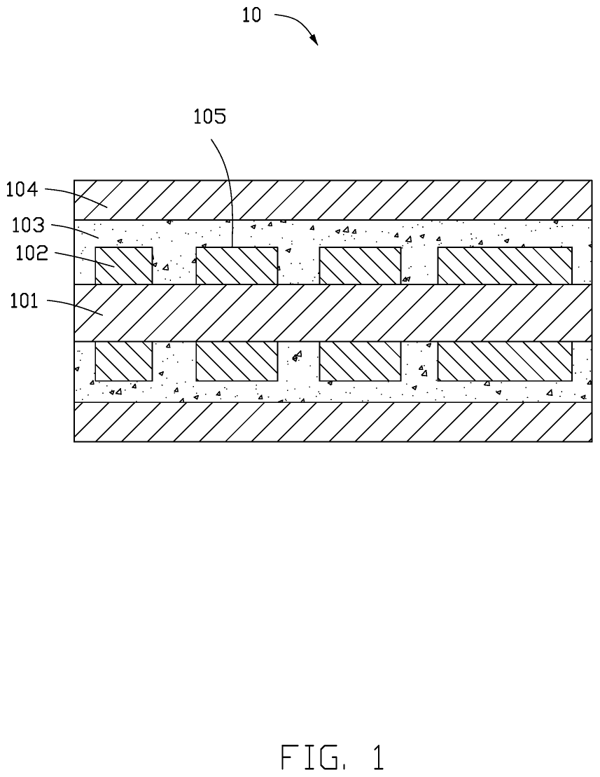

Step S1, referring to FIG. 1, an inner laminated structure 10 is provided. The inner laminated structure 10 includes a conductive wiring layer 102 and a cover layer 104, the cover layer 104 is on the outermost side of the inner laminated structure 10, and the conductive wiring layer 102 includes a connection pad 105.

In one embodiment, a prefabricated wiring board is provided, the prefabricated wiring board is the inner laminated structure 10. The inner laminated structure 10 may include a first base board 101, the conductive wiring layer 102, an adhesive layer 103, and the cover layer 104. The conductive wiring layer 102 is disposed on a surface of the first base board 101, the adhesive layer 103 is disposed on a side of the conductive wiring layer 102 away from the first base board 101, and the cover layer 104 is disposed on a side of the adhesive layer 103 away from the conductive wiring layer 102. The cover layer 104 is bonded with the first base board 101 and the conductive wiring layer 102 through the adhesive layer 103 and covers the conductive wiring layer 102.

In one embodiment, the inner laminated structure 10 is a double-layer plate, two conductive wiring layers 102 are disposed on opposite surfaces of the first base board 101, and two cover layers 104 are bonded with the two conductive wiring layers 102 through two adhesive layers 103.

In one embodiment, the inner laminated structure 10 does not include a solder mask. The solder mask has a limited etching accuracy, so small-size and high-precision etching and component placement is difficult to achieve. The omitting of the solder mask means that the cover layer 104 provides protection for the inner laminated structure 10, so that the manufacturing method is simplified, the cost is reduced, and the reliability of product is improved.

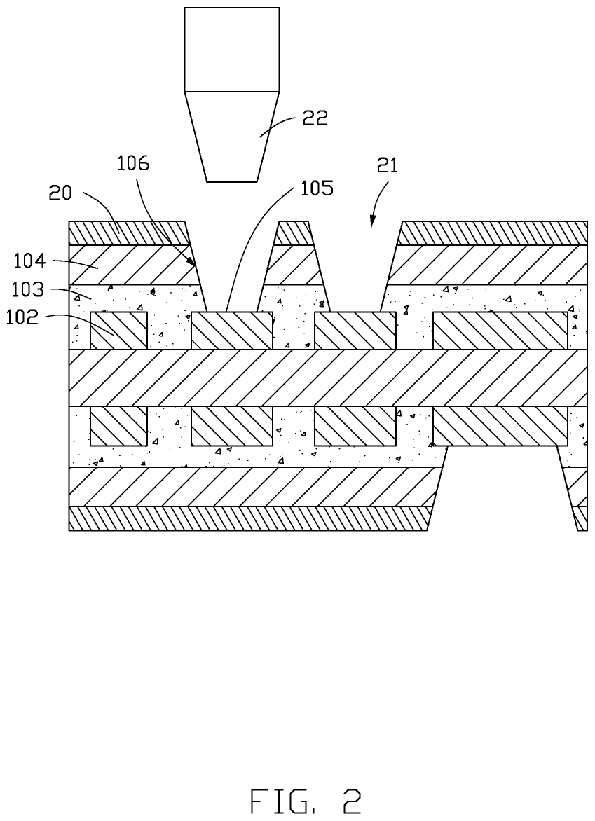

Step S2, referring to FIG. 2, a mask 20 is provided on a side of the cover layer 104 away from the conductive wiring layer 102. The mask 20 defines a plurality of first openings 21 penetrating the mask 20. The cover layer 104 is etched with a laser cutting head 22 through the mask 20 to form a second opening 106 to expose the connection pad 105.

In one embodiment, the mask 20 covers a surface of the cover layer 104, and the laser cutting head 22 emits laser light to etch the inner laminated structure 10. In the etching process, at least part of the cover layer 104 corresponding to the first opening 21 is removed to form the second opening 106.

In one embodiment, the mask 20 may be a prefabricated structure, and the prefabricated mask 20 can be used again.

In one embodiment, if the inner laminated structure 10 includes the adhesive layer 103, part of the adhesive layer 103 corresponding to the first opening 21 is removed in the etching process, to expose the connection pad 105.

In one embodiment, in a direction perpendicular to the inner laminated structure 10, a diameter of the second opening 106 gradually increases from the inside to the outside of the inner laminated structure 10. In one embodiment, the second opening 106 has a trapezoid shape which tapers downwards, a top of the second opening 106 is wider than a bottom of the second opening 106. Such second opening 106 promotes release of any gas in the subsequent printing process.

In one embodiment, there are multiple first openings 21 and second openings 106. The multiple second openings 106 are spaced apart from each other.

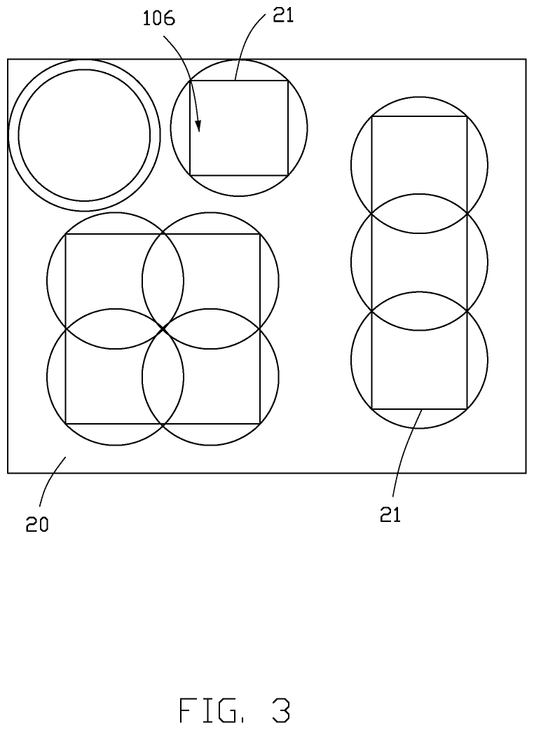

In one embodiment, the multiple second openings 106 are of different sizes and are formed in one scanning path of the laser cutting head 22. In the etching process, due to the existence of the mask 20, the laser cutting head 22 etches the inner laminated structure 10 only when scanning to the first opening 21. That is, etching with the laser in cooperation with the mask 20 reduces the replacement of the laser cutting head 22 and the adjustment of energy parameters, so that the etching of the multiple second openings 106 can be realized in one scanning process, the manufacturing efficiency is improved. Referring to FIG. 3, using laser in cooperation with the mask 20, the etching of the multiple second openings 106 in one scanning process is realized, so that damage to the inner laminated structure 10 caused by over-etching is avoided and the etching accuracy is improved. In the etching process, a shape of the second opening 106 is determined by a shape of the first opening 21 on the mask 20, and is not limited by a maximum rounding of the laser cutting head 22.

Step S3, a surface treatment is applied to the inner laminated structure 10.

Step S31, the mask 20 is removed.

In one embodiment, the removed mask 20 can be used again in the above processes.

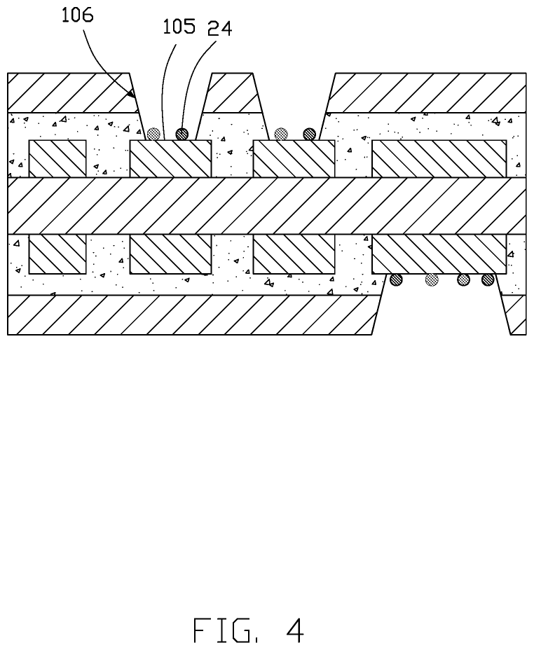

Step S32, referring to FIG. 4, residue 24 may exist in the second opening 106 after laser etching. The residue 24 may be residue of glue or debris after etching. The residue 24 in the second opening 106 is removed by plasma or other degumming process to fully expose a surface of the connection pad 105.

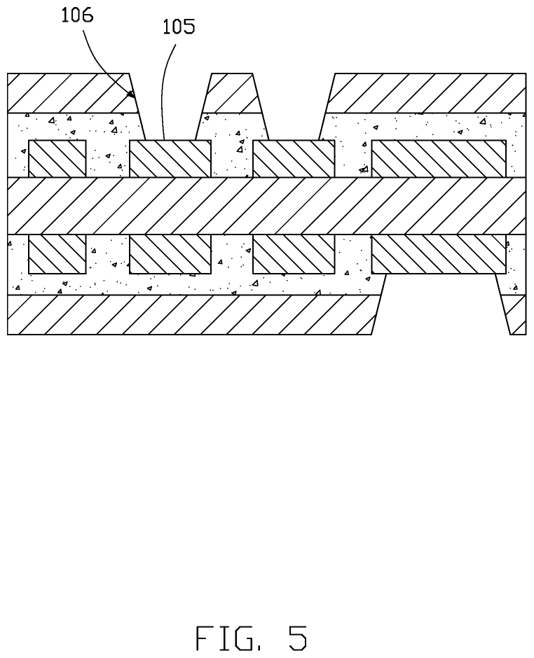

Step S33, referring to FIG. 5, the surface treatment is applied to the surface of the connection pad 105. The surface treatment can improve the finish and flatness of the connection pad 105.

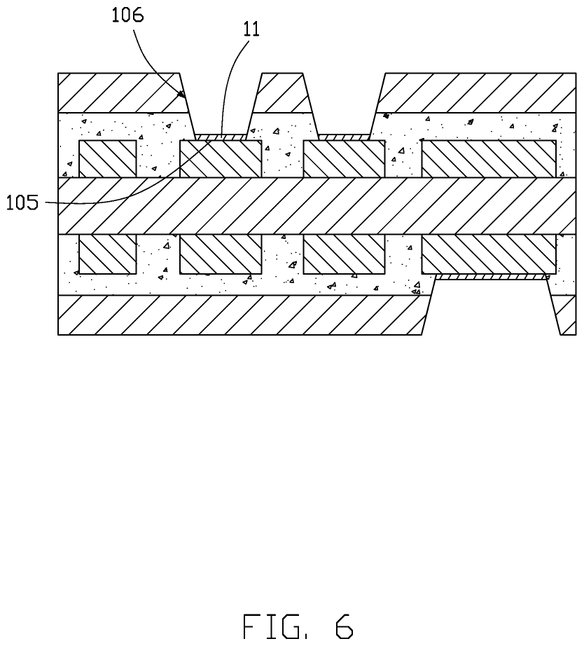

Step S34, referring to FIG. 6, a metal coating 11 is formed on the surface of the connection pad 105 exposed from the second opening 106. In one embodiment, the metal coating 11 is formed by chemical vapor deposition or physical vapor deposition, the metal coating 11 may be of nickel or of gold.

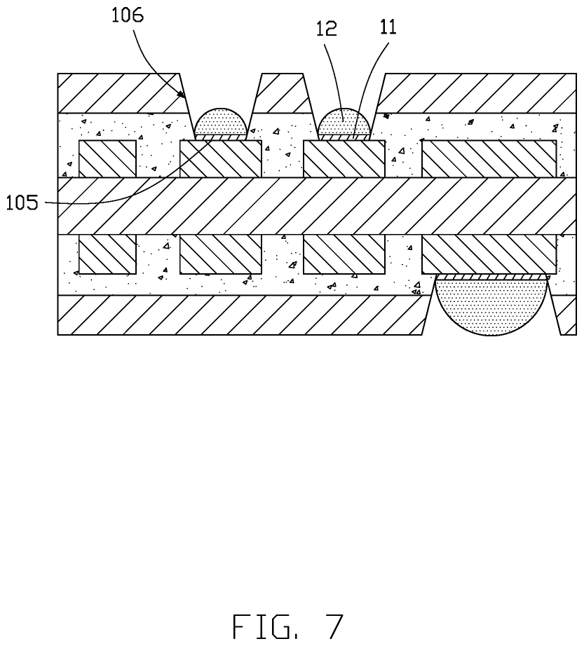

Step S35, referring to FIG. 7, a conductive paste 12 is formed in the second opening 106 to electrically connect the metal coating 11. That is, the conductive paste 12 is electrically connected with the connection pad 105 through the metal coating 11.

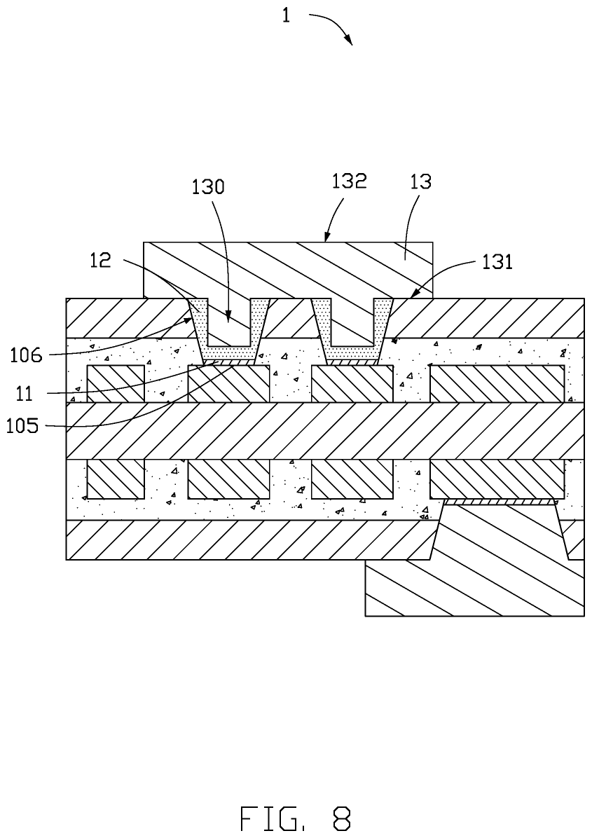

Step S4, referring to FIG. 8, an electronic component 13 is provided to electrically connect with the connection pad 105.

In one embodiment, at least part of the electronic component 13 is disposed in the second opening 106 and is electrically connected with the connection pad 105 through the conductive paste 12. Specifically, the electronic component 13 includes a first surface 131 and a second surface 132 opposite to each other, the first surface 131 is in contact with the inner laminated structure 10, and the second surface 132 is on a side of the electronic component 13 away from the inner laminated structure 10. The electronic component 13 also includes two connection pins 130, which are arranged in the second opening 106 and electrically connected with the metal coating 11 through the conductive paste 12. The two connection pins 130 can be arranged in two adjacent second openings 106. When the two connection pins 130 are pressed down, the conductive paste 12 arranged in each second opening 106 with narrow bottom and wide top gradually fills the second opening 106, and gas in the second opening 106 is allowed sufficient time to be discharged.

Referring to FIG. 9, the circuit board 1 prepared by the above manufacturing method is also disclosed.

The circuit board 1 includes the inner laminated structure 10, the metal coating 11, the conductive paste 12, and the electronic component 13.

The inner laminated structure 10 includes the first base board 101, the conductive wiring layer 102, the adhesive layer 103, and the cover layer 104. The conductive wiring layer 102 is disposed on a surface of the first base board 101, the adhesive layer 103 is disposed on a side of the conductive wiring layer 102 away from the first base board 101, and the cover layer 104 is disposed on a side of the adhesive layer 103 away from the conductive wiring layer 102. The cover layer 104 is bonded with the first base board 101 and the conductive wiring layer 102 through the adhesive layer 103 and covers the conductive wiring layer 102.

In one embodiment, the inner laminated structure 10 is a double-layer plate, two conductive wiring layers 102 are disposed on opposite surfaces of the first base board 101, and two cover layers 104 are bonded with the two conductive wiring layers 102 through two adhesive layers 103.

In one embodiment, the inner laminated structure 10 does not include a solder mask. The solder mask has a limited etching accuracy, so it is difficult to realize small-size and high-precision etching and component placement. The omitting of the solder mask means that the cover layer 104 provides protection for the inner laminated structure 10, so that the manufacturing method is simplified, the cost is reduced, and the reliability of product is improved.

The inner laminated structure 10 also includes the second opening 106, and the conductive wiring layer 102 includes the connection pad 105. The second opening 106 penetrates parts of the adhesive layer 103 and the cover layer 104 to expose at least part of the connection pad 105.

In a direction perpendicular to the inner laminated structure 10, a diameter of the second opening 106 gradually increases from the inside to the outside of the inner laminated structure 10. In one embodiment, the second opening 106 has a downwardly-tapering trapezoidal cross-section, an edge of the second opening 106 in contact with the connection pad 105 is a bottom edge of the trapezoid shape.

The metal coating 11 is disposed on a surface of the connection pad 105 in the second opening 106. In one embodiment, the metal coating 11 is formed by chemical coating or physical coating, the metal coating 11 may be of nickel or gold.

In one embodiment, the conductive paste 12 is disposed in the second opening 106 and fills at least part of the second opening 106, the conductive paste 12 is electrically connected with the metal coating 11.

The electronic component 13 is electrically connected with the conductive wiring layer 102 through the metal coating 11.

In one embodiment, the electronic component 13 includes a first surface 131 and a second surface 132 opposite to each other, the first surface 131 is in contact with the inner laminated structure 10, and the second surface 132 is on a side of the electronic component 13 away from the inner laminated structure 10. The electronic component 13 also includes two connection pins 130, which are arranged in the second opening 106 and electrically connect with the metal coating 11 through the conductive paste 12. The two connection pins 130 can be arranged in two adjacent second openings 106. In other embodiments, the first surface 131 of the electronic component 13 is not in contact with the inner laminated structure 10.

In one embodiment, the cover layer 104 is made of an elastic polymer material, a material of the cover layer 104 includes one of a group consisting of liquid crystal polymer, polypropylene, polyethylene terephthalate, polyimide, polytetrafluoroethylene, polyolefin, and a combination thereof. When the first surface 131 is in contact with the covering layer 104, the cover layer 104 of the elastic polymer material absorbs a part of the pressure when the electronic component 13 is pressed against the inner laminated structure 10, thereby avoiding rupture of the electronic component 13.

The above is only a preferred embodiment of the present disclosure, and is not intended to limit the scope of the present disclosure. Although embodiments of the present disclosure are described above, it is not intended to limit the present disclosure. The present disclosure may be modified or modified to equivalent variations without departing from the technical scope of the present disclosure by any person skilled in the art. Any simple modifications, equivalent changes and modifications made to the above embodiments remain within the scope of the technical solutions of the present disclosure.

What is claimed is:

1. A method for manufacturing a circuit board, comprising:
providing an inner laminated structure, the inner laminated structure comprising a conductive wiring layer and a cover layer, the cover layer being on an outermost side of the inner laminated structure, the conductive wiring layer comprising a connection pad;
providing a mask on a side of the cover layer away from the conductive wiring layer, the mask defining a plurality of first openings penetrating the mask;
laser etching the cover layer through the mask to form a second opening exposing the connection pad;
surface treating the inner laminated structure; and
providing an electronic component and electrically connecting the electronic component with the connection pad.

2. The method of claim 1, wherein in a direction perpendicular to the inner laminated structure, a diameter of the second opening gradually increases from the inside to the outside of the inner laminated structure.

3. The method of claim 1, wherein the second opening is multiple in number, the multiple second openings are spaced apart from each other and have different sizes, the multiple second openings are formed in one scanning path of a lase cutting head.

4. The method of claim 1, wherein surfacing treating the inner laminated structure comprises:
removing residue in the second opening;
surface treating a surface of the connection pad exposed from the second opening;
forming a metal coating on the surface of the connection pad exposed from the second opening.

5. The method of claim 4, wherein the metal coating is formed by chemical vapor deposition or physical vapor deposition.

6. The method of claim 1, wherein before surface treating the inner laminated structure, the method further comprises removing the mask.

7. The method of claim 1, wherein before electrically connecting the electronic component with the connection pad, the method further comprises forming a conductive paste in the second opening, at least a part of the electronic component is disposed in the second opening and is electrically connected with the conductive wiring layer through the conductive paste.

8. The method of claim 1, wherein the cover layer is made of an elastic polymer material.

9. A circuit board comprising:
an inner laminated structure comprising a conductive wiring layer, a cover layer, and an opening, wherein the cover layer is on an outermost side of the inner laminated structure, the conductive wiring layer comprises a connection pad exposed from the opening;
a metal coating disposed on a surface of the connection pad in the opening; and
an electronic component electrically connected with the conductive wiring layer through the metal coating.

10. The circuit board of claim 9, wherein in a direction perpendicular to the inner laminated structure, a diameter of the opening gradually increases from the inside to the outside of the inner laminated structure.

11. The circuit board of claim 10, wherein the opening has a downwardly-tapering trapezoidal cross-section, an edge of the opening in contact with the connection pad is a bottom edge of the trapezoid.

12. The circuit board of claim 9, wherein a material of the cover layer comprises one of a group consisting of liquid crystal polymer, polypropylene, polyethylene terephthalate, polyimide, polytetrafluoroethylene, polyolefin, and a combination thereof.

13. The circuit board of claim 9, further comprising a conductive paste, wherein the conductive paste infills at least a part of the opening and is electrically connected with the metal coating.

14. The circuit board of claim 9, wherein the metal coating is made of nickel or gold.

15. The circuit board of claim 9, wherein the inner laminated structure further comprises a base board and an adhesive layer, the conductive wiring layer is disposed on a surface of the base board, the cover layer is bonded with the base board through the adhesive layer and covers the conductive wiring layer, the opening penetrates the cover layer and the adhesive layer to expose the connection pad.
